(19) United States
(12) Patent Application Publication
(10) Pub. No.: US 2024/0096645 A1
(43) Pub. Date: Mar. 21, 2024

(54) SOI WAFER

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Ziwen WANG, Shanghai (CN); Minghao LI, Shanghai (CN); Hongtao XU, Shanghai (CN); Meng CHEN, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 18/518,555

(22) Filed: Nov. 23, 2023

Related U.S. Application Data
(62) Division of application No. 17/586,437, filed on Jan. 27, 2022.

(30) Foreign Application Priority Data
Oct. 29, 2021 (CN) 202111271381.3

(51) Int. Cl. H01L 21/324; H01L 21/762

(52) U.S. Cl. CPC H01L 21/3247; H01L 21/76254

(57) ABSTRACT

A SOI wafer is disclosed. The SOI wafer may be characterized by surface roughness of a top silicon layer of the SOI wafer is less than 4 Å, thickness uniformity of the top silicon layer is within ±1%, and a total number of particles on a surface of the top silicon layer of the SOI wafer, measured with setting of 37 nm of SPx detection threshold, is less than 100.

### FIELD OF THE INVENTION

The present invention generally relates to a semiconductor technical field, and specifically, relates to a SOI wafer.

### BACKGROUND OF THE INVENTION

As post Moore's law era continues, people harshly demand structure, uniformity and conformity of semiconductor silicon wafers. Nowadays SOI (Silicon on Insulator) wafer is broadly applied in fields of microelectronics, optics and photoelectricity, and faces more challenges in related materials.

Preferably, the thinner top silicon layer of SOI devices is the better, but traditional mechanical polishing has problems of ununiform thickness, great roughness and tendency to introduce surface defects, etc. To replace the traditional mechanical polishing, oftentimes a process of final thermal processing, including long-time thermal processing and rapid thermal annealing, may be performed. Surface roughness of such a wafer may be improved but small particles in a windmill-shaped area, which are shallow pits formed during the rapid thermal annealing, are found on a surface of the wafer, as shown in FIG. 1.

Although particles smaller than 90 nm could not draw people's attention before, this is an inevitable issue as semiconductor devices are getting more integrated in smaller sizes.

As stated above, the present invention provides a solution to solve above-mentioned technical problem.

### SUMMARY OF THE INVENTION

An object of the present invention is to provide a SOI wafer with good surface roughness, uniformity of thickness of a top silicon layer, and a total number of particles which is less than 100, measured with SPx detection threshold of 37 nm.

An aspect of the present invention is to provide a SOI wafer, characterized by: surface roughness of a top silicon layer of the SOI wafer is less than 4 Å, thickness uniformity of the top silicon layer is within ±1%, and a total number of particles on a surface of the top silicon layer of the SOI wafer, measured with setting of 37 nm of SPx detection threshold, is less than 100.

The present invention has advantages that: after performing the steps of rapid thermal annealing and long-time thermal annealing with the specific condition in the specific order, optional oxide thinning according to a required top silicon layer may be performed to obtain a SOI wafer with a better surface which satisfies requirements of shrinking device feature sizes and promoting performance and yield. The SOI wafer may supply feasible substrate material for silicon-based devices in post Moore's law era.

### BRIEF DESCRIPTION OF THE DRAWINGS

Various objects and advantages of the present invention will be more readily understood from the following detailed description when read in conjunction with the appended drawing, in which:

FIG. 1a shows SPx particle mapping @90 nm after rapid thermal annealing of a current technology;

FIG. 1B shows SPx particle mapping @37 nm after rapid thermal annealing of a current technology;

FIG. 1c shows a total number of particles in various sizes, measured with SPx, after rapid thermal annealing of a current technology, in which “11 s” represents a detection threshold;

FIG. 2 shows an optional flow chart of the method according to the invention;

FIG. 3 shows a curve representing an integrated process of long-time thermal annealing and oxide thinning;

FIG. 4a shows an AFM picture of a surface before the rapid thermal annealing;

FIG. 4b shows an AFM picture of a surface after the rapid thermal annealing;

FIG. 4c shows an AFM picture of a surface after the long-time thermal annealing;

FIG. 4d shows a picture with SPx particle mapping @37 nm after the rapid thermal annealing;

FIG. 4e shows a picture with SPx particle mapping @37 nm after the long-time thermal annealing;

FIG. 4f shows the total number of particles on the SOI wafer in the first embodiment, measured with SPx particle mapping @37 nm;

FIG. 5a shows an AFM picture of a surface before the rapid thermal annealing;

FIG. 5b shows an AFM picture of a surface after the rapid thermal annealing;

FIG. 5c shows an AFM picture of a surface after the oxide thinning;

FIG. 5d shows an AFM picture of a surface after the long-time thermal annealing;

FIG. 5e shows a picture with SPx particle mapping @37 nm after the rapid thermal annealing;

FIG. 5f shows a picture with SPx particle mapping @37 nm after the oxide thinning;

FIG. 5g shows a picture with SPx particle mapping @37 nm after the long-time thermal annealing;

FIG. 5h shows the total number of particles on the SOI wafer in the second embodiment, measured with SPx particle mapping @37 nm.

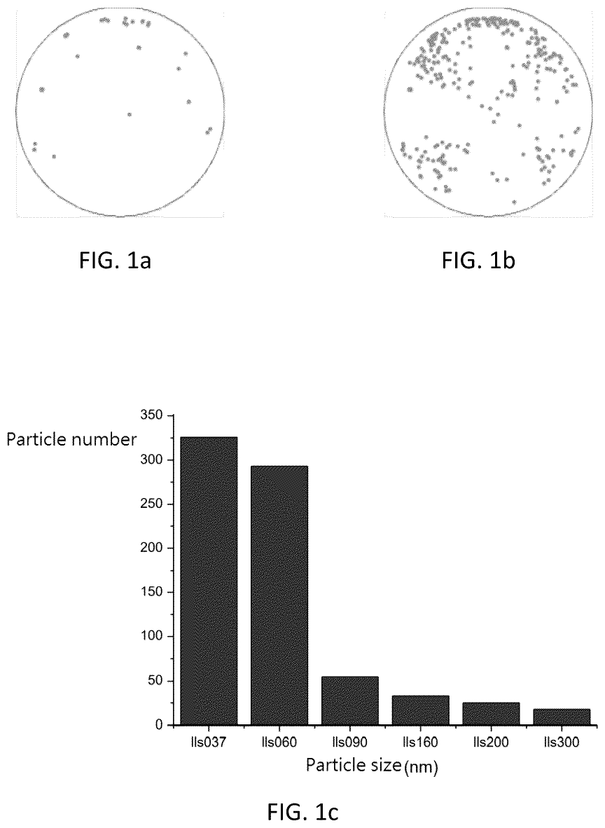

### DESCRIPTION OF EMBODIMENTS OF THE INVENTION

With widely and deeply experiments, inventors found that through combining rapid thermal annealing and long-time thermal annealing in a certain condition, pits formed during the rapid thermal annealing may be eventually removed due to migration and reconstruction of silicon atoms in an area having particle distribution. As such, a SOI wafer with a better surface may be obtained to supply feasible substrate material for silicon-based devices in post Moore's law era.

Further, in a preferred embodiment, despite more time to perform the long-time thermal annealing that affects cost and quality to be considered, for those implementations that requires for oxide thinning, combining long-time thermal annealing and oxide thinning may compensate spent time, so as to obtain a better SOI wafer in quality with less total processing time, which is an unforeseen effect.

Unless a clear rule or definition is given, a term of “or” comprises “and.” A term of “and” is equivalent to Boolean algebra “AND,” the term of “or” is equivalent to Boolean algebra “OR,” and “AND” is a subset of “OR.”

For example, terms of “comprise,” “consist of,” “have,” “contain” and its varieties may be interpreted in a broad way to comprise listed objects, all equivalents and other unlisted objects. In addition, elements, parts, technologies, steps or other illustration introduced with the terms of “comprise,” “consist of,” or “have” may be interpreted as considering the same elements, parts, technologies, steps, or those with illustration of terms of “basically composed by,” “formed by,” “chosen from a group of” or other illustration.

Please note the following paragraphs to understand aspects of the present invention.

### Terminology

In the present disclosure, “AFM roughness” indicates a rms (Root Mean Square) value of surface roughness measured with AFM (Atomic Force Microscope) representing surface roughness in a square area of 10 μm of each side, and the surface roughness is rms roughness Rq.

In the present disclosure, “surface defect detection” is performed with model number of “Surfscan 7” provided by KLATencor, the surface defect detection may be performed with a setting of detection threshold, such as 90 nm or 37 nm. “SPx” is the same as “surface defect detection,” and may be interchangeable used.

Those skilled in the art can understand that all of “SPx particle mapping @90 nm,” “SPx particle @90 nm,” or “SPx mapping @90 nm” indicate particle number measured with aforesaid “Surfscan 7” with setting of 90 nm detection threshold. Similarly, “SPx particle mapping @37 nm” has similar meaning but with different setting of detection threshold.

SOI Wafer and Steps for Making the Same

A SOI wafer is provided in which surface roughness of a top silicon layer of the SOI wafer is measured with AFM roughness, rms roughness Rq is less than 4 Å, and thickness uniformity of the top silicon layer is within ±1%.

The SOI wafer may be obtained with a method according to the present invention. The method may comprise a step (I) of rapid thermal annealing and a step (II) of long-time thermal annealing to eliminate small particles in a windmill-shaped area, which are formed during the step (I) of rapid thermal annealing.

Specifically, the method of final processing a SOI wafer may comprise: the step (I) of rapid thermal annealing and the step (II) of long-time thermal annealing, wherein a step (I) of rapid thermal annealing comprises: providing a first wafer to be processed for making the SOI wafer; rapid thermal annealing the first wafer to get a second wafer which has been rapid-thermal-annealed; wherein the rapid thermal annealing comprises a first heating process and a first annealing process, the first heating process is performed in an atmosphere of a mixture of argon gas and hydrogen gas, and volume of the hydrogen gas is less than 10% of whole volume of the mixture, and the first annealing process is performed in an atmosphere of argon gas and optionally hydrogen gas, and volume of the hydrogen gas is no greater than 10% of whole volume of the mixture; and the step (II) of long-time thermal annealing comprises: long-time thermal annealing the second wafer obtained from the step (I) to get the SOI wafer; wherein the long-time thermal annealing comprises a second heating process and a second annealing process, the second heating process is performed in an atmosphere of a mixture of argon gas and hydrogen gas, and volume of the hydrogen gas is less than 10% of whole volume of the mixture, and the second annealing process is performed in an atmosphere of argon gas and optionally hydrogen gas, and volume of the hydrogen gas is no greater than 10% of whole volume of the mixture.

In a preferred embodiment of the present invention, after the step (II) of long-time thermal annealing, a step (III) of oxide thinning may be performed to precisely control thickness uniformity of the top silicon layer.

In a preferred embodiment of the present invention, the steps of (II) and (III) may be integrated together.

A further step (IA) of oxide thinning may be performed between the steps (I) and (II).

Currently, rapid thermal annealing is always used to final planarize SOI wafers. The main reason is to keep thickness uniformity of the top silicon layer, short processing time, and better performance, compared with polishing or chemical mechanical polishing (CMP).

However, the inventors found that despite improvement of uniformity and roughness that brought with rapid thermal annealing, small particles in a windmill-shaped area formed on a surface of the wafers (detected when setting the detection threshold of 37 nm). Such particles generally are shallow pits formed during the rapid thermal annealing. Because only particles with 90 nm sizes or above draw semiconductor industry's attention before, no solution is created for this issue. The pits definitely cause bad effects on yield of devices on the SOI wafers since the devices are getting smaller and thinner. Therefore, with widely and deeply experiments, inventors found that through combining rapid thermal annealing and long-time thermal annealing in a certain condition, pits formed during the rapid thermal annealing may be eventually removed due to migration and reconstruction of silicon atoms in an area having particle distribution. As such, a SOI wafer with a better surface may be obtained to supply feasible substrate material for silicon-based devices in post Moore's law era.

The SOI wafers of the present invention overcome above-mentioned technical problems. The surface roughness of the top silicon layer of the SOI wafers is measured with AFM roughness, rms roughness Rq is less than 4 Å, and thickness uniformity of the top silicon layer is within ±1%.

Specifically, a total number of particles on a surface of the top silicon layer of the SOI wafer, measured with setting of 37 nm of SPx detection threshold, is less than 100. This means that through the figure showing distribution of particles with the SPx detection, the distribution of the small particles in the windmill-shaped area is recovered, especially when the smallest size of the particles is 37 nm. The distribution of particles in the windmill-shaped area designates shallow pits with particular distribution and size smaller than 90 nm detected in the SPx detection mainly, but is not limited to in the windmill-shaped area. The shape of the distribution depends on thermal distribution, geographic parameters, etc. in a reacting chamber of the rapid thermal annealing.

In a preferred example of the present invention, the process does not comprise a CMP step.

In the present invention, the surface of the SOI wafer may be optimized, especially particle distribution on the surface of the SOI wafer generating after the rapid thermal annealing may be solved, even when the CMP step is not involved.

In a preferred example of the present invention, the first wafer to be processed may be obtained with a pre-processing step comprising ion implantation slicing technology. Specifically, the first wafer may be obtained with a Smart Cut™ technology used in the pre-processing step. Taking a SOI wafer obtained with the Smart Cut™ technology for example, the surface roughness after slicing is >10 Å.

With current technologies, harmed layer is generated due to ion implantation in the ion implantation slicing, so as to present a greater surface roughness. However, the inventors found that such a wafer may be processed with the method of the present invention to make an end product which shows rms roughness Rq is no greater than 4 Å, thickness uniformity of the top silicon layer is within ±1%, and the total number of particles on the surface of the top silicon layer of the SOI wafer, measured with surface defect detection set with 37 nm of SPx detection threshold, is less than 100.

It may be readily understood that the “first wafer to be processed” is not limited to a SOI structured wafer obtained with Smart Cut™ technology, which is only for example but not intended to be a limitation.

Rapid Thermal Annealing

Specifically, the step (I) of rapid thermal annealing comprises: providing a first wafer to be processed for making the SOI wafer; rapid thermal annealing the first wafer to get the second wafer which has been rapid-thermal-annealed; wherein the rapid thermal annealing comprises a first heating process and a first annealing process, the first heating process is performed in an atmosphere of a mixture of argon gas and hydrogen gas, and volume of the hydrogen gas is less than 10% of whole volume of the mixture, and the first annealing process is performed in an atmosphere of argon gas and optionally hydrogen gas, and volume of the hydrogen gas is no greater than 10% of whole volume of the mixture.

Preferably, oxygen gas content in the first heating process is about 0.01-10% of whole volume of the mixture; 1-10% is preferred, and may be any point falls within the disclosed ranges, such as 1%, 2%, 3%, 5%, 10%. Most preferably, the oxygen gas content may be no greater than 3% of whole volume of the mixture, such as 0.01-3%. Rapid thermal annealing is usually performed in the atmosphere of the mixture of argon gas and hydrogen gas in which the hydrogen gas may be used to exclude oxygen gas which deteriorates particles in the surface and to etch the surface of the wafers in a high temperature. As such, the content of hydrogen gas is crucial.

Preferably, the first annealing process may be performed in an atmosphere of pure argon gas.

Preferably, the first annealing process may be performed in an atmosphere in which content of hydrogen gas is no greater than 3% of whole volume of the mixture used.

The rapid thermal annealing may be performed in a constant pressure or reduced pressure.

Protection gas used in the first heating process and that used in the first annealing process may be the same or different. For instance, the atmosphere of the first heating process may be continued to carry out the first annealing process or may be switched to another atmosphere of pure argon gas.

Ordinary technologies may be used to fulfill other conditions used in the present invention as long as no limitation toward the present invention is created.

For example, annealing temperature may fall within 1100° C.-1300° C.

For example, preferred time period of annealing may fall within 1 s-120 s, and more preferably, 10 s-60 s, and more preferred annealing temperature may fall within 1150° C.-1250° C.

For example, the pressure in the reacting chamber for rapid thermal annealing may be constant pressure, and optionally, low pressure, which may fall within 1 mbar-1010 mbar.

For example, heating speed in the rapid thermal annealing may fall within 30-100° C./s, and 50-70° C./s preferred.

For example, cooling speed in the rapid thermal annealing may fall within 30-100° C./s, and 50-70° C./s preferred.

If no specific indication is provided, those conditions listed above are only for example but not intended to limit the present invention.

Long-Time Thermal Annealing

The step (II) of long-time thermal annealing comprises: long-time thermal annealing the second wafer obtained from the step (I) to get the SOI wafer product; wherein the long-time thermal annealing comprises a second heating process and a second annealing process, the second heating process is performed in an atmosphere of a mixture of argon gas and hydrogen gas, and volume of the hydrogen gas is less than 10% of whole volume of the mixture, and the second annealing process is performed in an atmosphere of argon gas and optionally hydrogen gas, and volume of the hydrogen gas is no greater than 10% of whole volume of the mixture.

Preferably, oxygen gas content in the second heating process is about 0.01-10% of whole volume of the mixture; 1-10% is preferred, and may be any point falls within the disclosed ranges, such as 1%, 2%, 3%, 5%, 10%. Most preferably, the oxygen gas content may be no greater than 3% of whole volume of the mixture, such as 0.01-3%.

Preferably, the second annealing process may be performed in an atmosphere of pure argon gas.

Preferably, the second annealing process may be performed in an atmosphere in which content of hydrogen gas is no greater than 3% of whole volume of the mixture used.

Protection gas used in the second heating process and that used in the second annealing process may be the same or different. For instance, the atmosphere of the second heating process may be continued to carry out the second annealing process or may be switched to another atmosphere of pure argon gas.

Protection gas used in the second heating process and that used in the first heating process may be the same or different.

Ordinary technologies may be used to fulfill other conditions used in the present invention as long as no limitation toward the present invention is created.

For example, the second wafer may be loaded into a CVD reacting furnace or vertical furnace to be long-time thermal annealed.

For example, a temperature when the second wafer is loaded may be 500° C.-800° C., and preferably, 650° C. At this time, an atmosphere may be of pure argon and held for 1 min-10 min, and preferably, 5 min.

For example, a heating speed may fall within 0.5-20° C./min, and preferably, 0.5-10° C./min.

For example, after heating to a target temperature and starting to anneal, the atmosphere of the second heating process may be kept optionally or switched to the one of pure argon.

For example, the temperature of this time may fall within 1050° C.-1250° C., and preferably, 1100° C.-1200° C.

For example, annealing time period may fall within 1 min-120 min, and preferably, 30 min-60 min.

For example, the atmosphere may be switched to the one of pure argon gas after the long-time thermal annealing, and the temperature may be cooled to 500° C.-800° C., and preferably, 650° C.

For example, the cooling speed at this time may fall within 0.5-10° C./min, and preferably, 0.5-5° C./min.

If no specific indication is provided, those conditions listed above are only for example but not intended to limit the present invention.

Oxide Thinning

It may be readily understood that through the step (I) of rapid thermal annealing and the step (II) of long-time thermal annealing, the roughness of the top silicon layer of the SOI wafer is no higher than 4 Å, thickness uniformity of the top silicon layer is within ±1%, and the total number of particles on the surface of the top silicon layer of the SOI wafer, measured with the surface defect detection set with 37 nm of SPx detection threshold, is less than 100.

To meet various requirements of thickness of the top silicon layer, the present invention provides oxide thinning which facilitates various thickness of the top silicon layer.

In an implementation of the present invention, after the step (II) of long-time thermal annealing, a step (III) of oxide thinning that precisely controls thickness uniformity of the top silicon layer may be performed. This means that after the step (II) of long-time thermal annealing, the step (III) of oxide thinning may be performed. Preferably, due to the step (III) of oxide thinning that precisely controls thickness uniformity of the top silicon layer, deviation of the thickness uniformity of the top silicon layer may be precisely controlled to fall within ±1%.

In an preferred implementation of the present invention, the steps of (II) and (III) may be integrated together. Optionally, after the long-time thermal annealing, the oxide thinning may be integrated directly.

For example, after the annealing, the atmosphere may be of pure argon gas and may be cooled to an oxidation temperature which may fall within 800° C.-1000° C., and preferably 900° C.-950° C., with a cooling rate of 0.5-10° C./min, and preferably, 0.5-5° C./min, for a time period which may depend on a target thickness, and the atmosphere for oxidation may be adapted to dry oxidation, wet oxidation or a combination of dry and wet oxidation.

In an implementation of the present invention, the steps of (II) and (III) may be performed in a furnace.

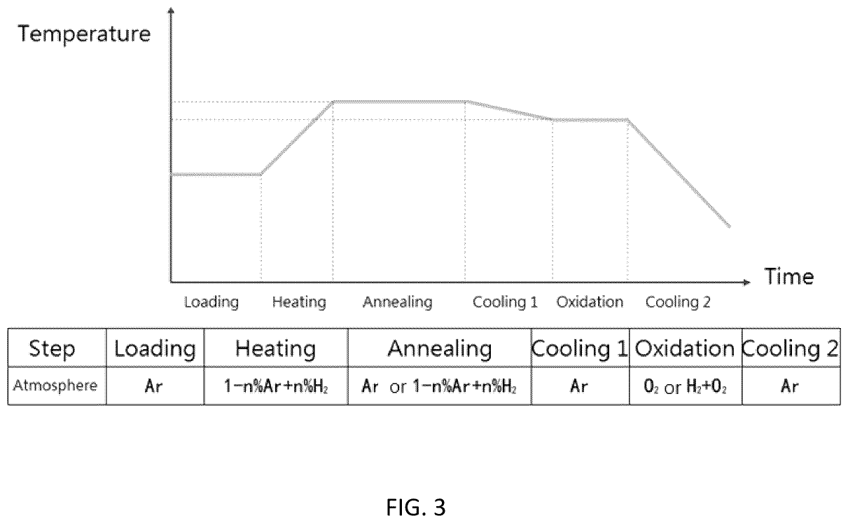

In a preferred implementation of the present invention, the steps of (II) and (III) may be performed in the very same furnace to cut down the cost. For example, as shown in FIG. 3, a curve representing relationship between a temperature in an integrated process of long-time thermal annealing and oxide thinning and the atmosphere, drawn in temperature-time axis.

The oxide thinning is not limited to being performed after the step (II) of long-time thermal annealing. In an implementation of the present invention, a further step (IA) of oxide thinning may be performed between the steps (I) and (II).

The step (III) of oxide thinning and/or the step (IA) of oxide thinning may be performed in an ordinary way.

For example, after the oxide thinning, a surface oxide layer of the SOI wafer may be removed with rinsing of HF solution, HF content of which may be less than 20%, and 5% is preferred.

For example, after the oxide thinning, the atmosphere may be switched to be of pure argon air, cooled slowly to 500° C.-800° C., and preferably 650° C., with a cooling rate which falls within 0.5-10° C./min, and preferably 0.5-5° C./min.

### Preferred Embodiments

The present disclosure illustrates various aspects of the embodiments according to the present invention, which may be implemented in various ways. Please note that structures and/or functionalities described here is only for description and those skilled in the art should understand that any one of the aspects may be implemented solely or in a combination. For instance, the device and/or method may be implemented in any number or field. Further, other structure and/or functionality may be used to implement the device and/or method.

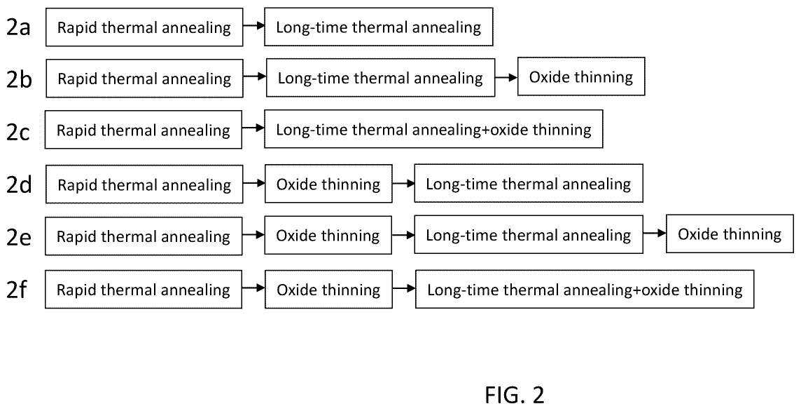

Specifically, a process according to the invention is shown in FIG. 2 which implements the following steps: 2a, step (I) of rapid thermal annealing, step (II) of long-time thermal annealing; 2b, step (I) of rapid thermal annealing, step (II) of long-time thermal annealing, step (II) of oxide thinning; 2c, step (I) of rapid thermal annealing, step (II) of long-time thermal annealing+step (II) of oxide thinning; 2d, step (I) of rapid thermal annealing, step (IA) of oxide thinning, step (II) of long-time thermal annealing; 2e, step (I) of rapid thermal annealing, step (IA) of oxide thinning, step (II) of long-time thermal annealing, step (II) of oxide thinning; 2f, step (I) of rapid thermal annealing, step (IA) of oxide thinning, step (II) of long-time thermal annealing+step (II) of oxide thinning. Please note that “+” means the both steps are integrated together.

Technical features of the present invention will be more readily understood from the following detailed description when read in conjunction with the appended drawing. Obviously, the drawings are only for illustrating some of the embodiments of the present invention. For those have ordinary skills in the art may obtain some other drawings of some other embodiments without creative work.

Please also note that the figures provided here are only exemplary. Only elements relative to the invention are shown therein. Actual number, shape, sizes, type and proportion may be varied in an implementation. Layout or arrangement may be more complicated.

Further, please note that specific details provided here are only for understanding the examples; however, those skilled in the art may understand how to implement these aspects without these details. Terms of “first” and “second” are used only for description but not intended to indicate or imply relative importance or limit number of features. Therefore, the feature which is described with “first” or “second” may be expressed or implied the number is single or plural. In the present disclosure, unless clear indication, “a plurality of” means two or more.

Embodiment Illustration

The AFM measurement is performed with Park NX-wafer, which is non-contact model, measurement range of which is 10 μm×10 μm, and solution of which is 512×512. If no clear indication, “roughness” denoted here is rms roughness measured with AFM.

### First Embodiment

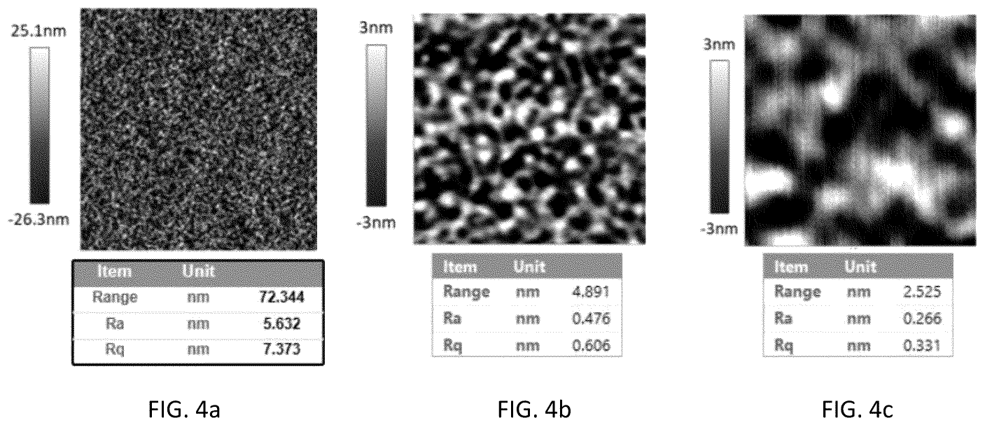

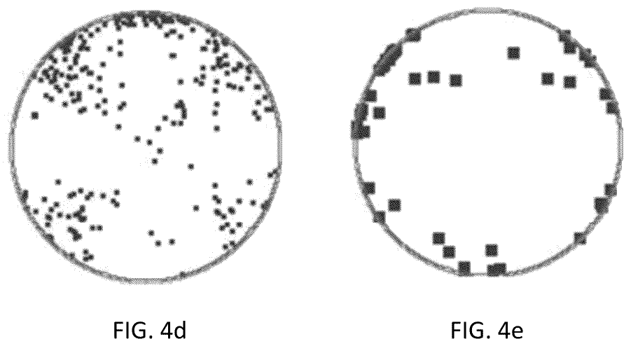

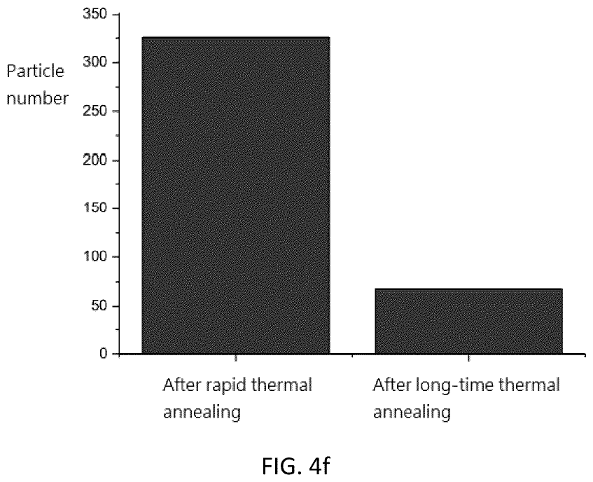

FIG. 4a shows an AFM non-contact scanning picture in 10 μm×10 μm of a surface of a SOI wafer obtained with Smart Cut™, and the surface roughness of the SOI wafer is 73.7 Å.

After rapid thermal annealing the wafer, an atmosphere of 97.5% Ar+2.5% H₂ is heated; during the annealing, the atmosphere is switched to be of pure argon gas in an annealing temperature of 1200° C. for an annealing time period of 30 s. The rapid thermal annealing is performed in a constant pressure; heating rate is 70° C./s, and cooling rate is 50° C./s.

FIG. 4b shows an AFM non-contact scanning picture in 10 μm×10 μm of the surface of the SOI wafer after the rapid thermal annealing, and the surface roughness of the SOI wafer is 6.1 Å.

After the rapid thermal annealing, the wafer is loaded into a CVD reacting furnace at a loading temperature of 650° C. in an atmosphere of pure argon air for holding 5 min.

Then, the atmosphere is switched to be of 97.5% Ar+2.5% H₂ and the wafer is heated with a heating rate of 5° C./min.

When reaching a target temperature, annealing starts. The atmosphere is switched to be of pure argon gas at 1100° C., and the wafer is annealed for 40 min.

After annealing, the atmosphere of pure argon gas is set, the wafer is then cooled to 650° C. with a cooling rate of 3° C./min.

FIG. 4c shows an AFM non-contact scanning picture in 10 μm×10 μm of the surface of the SOI wafer after the long-time thermal annealing, and the surface roughness of the SOI wafer is 3.3 Å.

FIG. 4a shows an AFM picture before the rapid thermal annealing; FIG. 4b shows an AFM picture after the rapid thermal annealing; FIG. 4c shows an AFM picture after the long-time thermal annealing; FIG. 4d shows a picture with SPx particle mapping @37 nm after the rapid thermal annealing; FIG. 4e shows a picture with SPx particle mapping @37 nm after the long-time thermal annealing; FIG. 4f shows the total number of particles on the SOI wafer shown in FIGS. 4c and 4d, measured with SPx particle mapping @37 nm. The result shows that rms surface roughness, Rq, of the top silicon layer of the SOI wafer product having a required thickness of the top silicon layer, analyzed with AFM roughness analysis, is no higher than 4 Å, and thickness uniformity of the top silicon layer is within ±1%.

### Second Embodiment

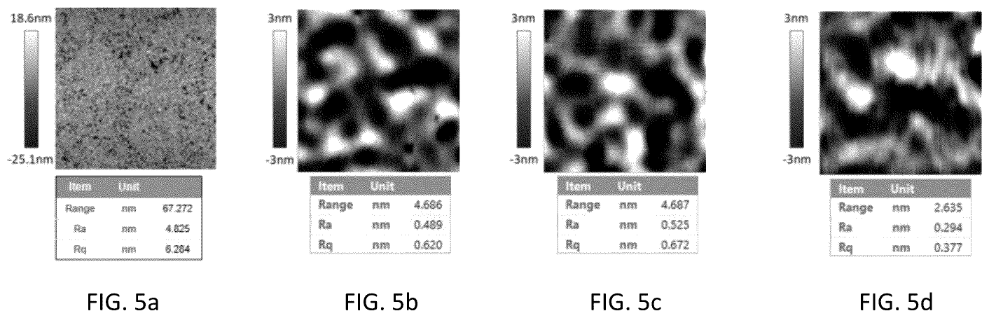

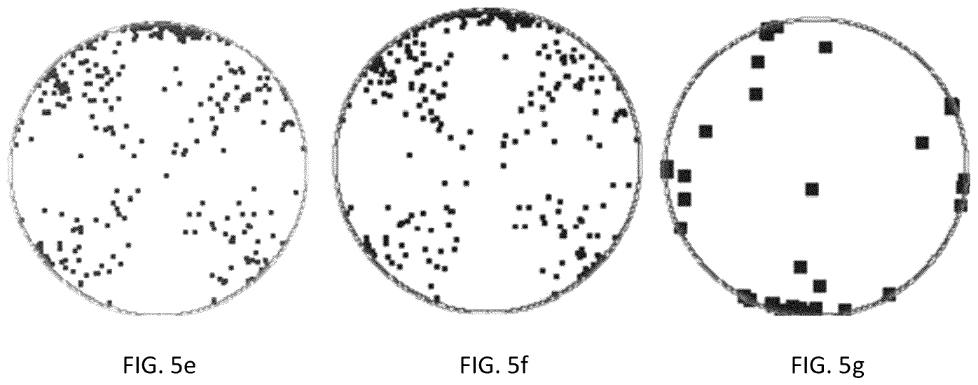

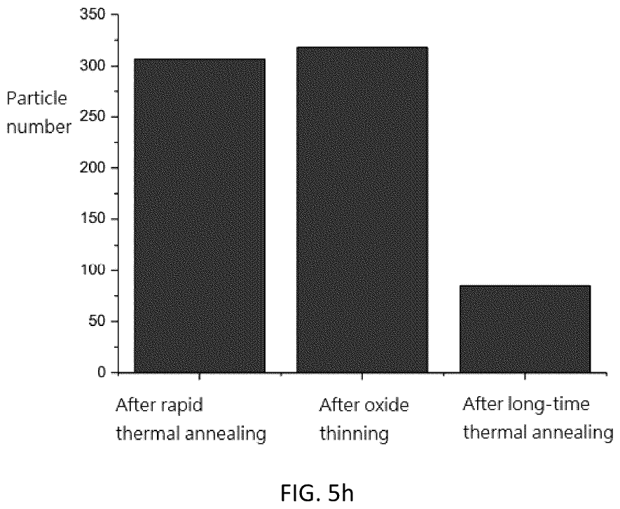

FIG. 5a shows an AFM non-contact scanning picture in 10 μm×10 μm of a surface of a SOI wafer obtained with Smart Cut™, and the surface roughness of the SOI wafer is 62.8 Å.

After rapid thermal annealing the wafer, an atmosphere of 97.5% Ar+2.5% H₂ is heated; during the annealing, the atmosphere is switched to be of pure argon gas in an annealing temperature of 1200° C. for an annealing time period of 30 s. The rapid thermal annealing is performed in a constant pressure; heating rate is 70° C./s, and cooling rate is 50° C./s.

FIG. 5b shows an AFM non-contact scanning picture in 10 μm×10 μm of the surface of the SOI wafer after the rapid thermal annealing, and the surface roughness of the SOI wafer is 6.2 Å.

After the rapid thermal annealing, the wafer is oxidized in an atmosphere of dry or wet oxide gas, wet oxide gas here, according to a target thickness at an oxidization temperature of 950° C.

After oxidation, a surface oxide layer of the wafer is removed in a HF solution, HF content of which is 5%, to get 1750 Å of thickness of a top silicon layer.

FIG. 5c shows an AFM non-contact scanning picture in 10 μm×10 μm of the surface of the SOI wafer after the long-time thermal annealing, and the surface roughness of the SOI wafer is 6.7 Å.

The wafer is then loaded into a CVD reacting furnace at a loading temperature of 650° C. in an atmosphere of pure argon air for holding 5 min.

Then, the atmosphere is switched to be of 97.5% Ar+2.5% H₂ and the wafer is heated with a heating rate of 5° C./min.

When reaching a target temperature, annealing starts. The atmosphere is switched to be of pure argon gas at 1100° C., and the wafer is annealed for 40 min.

After annealing, the atmosphere of pure argon gas is set, the wafer is then cooled to 650° C. with a cooling rate of 3° C./min.

FIG. 5d shows an AFM non-contact scanning picture in 10 μm×10 μm of the surface of the SOI wafer after the long-time thermal annealing, and the surface roughness of the SOI wafer is 3.8 Å.

FIG. 5a shows an AFM picture before the rapid thermal annealing; FIG. 5b shows an AFM picture after the rapid thermal annealing; FIG. 5c shows an AFM picture after the oxide thinning; FIG. 5d shows an AFM picture after the long-time thermal annealing; FIG. 5e shows a picture with SPx particle mapping @37 nm after the rapid thermal annealing; FIG. 5f shows a picture with SPx particle mapping @37 nm after the oxide thinning; FIG. 5g shows a picture with SPx particle mapping @37 nm after the long-time thermal annealing; FIG. 5h shows the total number of particles in the second embodiment, measured with SPx particle mapping @37 nm. The result shows that rms surface roughness, Rq, of the top silicon layer of the SOI wafer product having a required thickness of the top silicon layer, analyzed with AFM roughness analysis, is no higher than 4 Å, and thickness uniformity of the top silicon layer is within ±1%.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. In all instances, the scope of such claims shall be considered on their own merits in light of this disclosure, and such claims accordingly define the invention(s), and their equivalents or variations, that are protected thereby.

What is claimed is:

1. A SOI wafer, characterized by:
surface roughness of a top silicon layer of the SOI wafer is less than 4 Å, thickness uniformity of the top silicon layer is within ±1%, and a total number of particles on a surface of the top silicon layer of the SOI wafer, measured with setting of 37 nm of SPx detection threshold, is less than 100.

2. The SOI wafer according to claim 1, made with steps comprising a step (I) of rapid thermal annealing and a step (II) of long-time thermal annealing,
wherein the step (I) of rapid thermal annealing comprises:
providing a first wafer to be processed for making the SOI wafer;
rapid thermal annealing the first wafer to get a second wafer which has been rapid-thermal-annealed;
wherein the rapid thermal annealing comprises a first heating-up process and a first annealing process, the first heating-up process is performed in an atmosphere of a mixture gas of argon and hydrogen, and volume of the hydrogen is less than 10% of whole volume of the mixture gas, and the first annealing process is performed in an atmosphere of argon and optionally hydrogen, and volume of the hydrogen is no greater than 10% of whole volume of the mixture gas;
the step (II) of long-time thermal annealing comprises:
long-time thermal annealing the second wafer obtained from the step (I) to get the SOI wafer;
wherein the long-time thermal annealing comprises a second heating-up process and a second annealing process, the second heating-up process is performed in an atmosphere of a mixture gas of argon and hydrogen, and volume of the hydrogen is less than 10% of whole volume of the mixture gas, and the second annealing process is performed in an atmosphere of argon and optionally hydrogen, and volume of the hydrogen is no greater than 10% of whole volume of the mixture gas.

3. The SOI wafer according to claim 1, wherein after the step (II) of long-time thermal annealing, a step (III) of oxide thinning is performed to precisely control thickness uniformity of a top silicon layer.

4. The SOI wafer according to claim 3, wherein the steps of (II) and (III) are integrated together.

5. The SOI wafer according to claim 2, wherein a further step (IA) of oxide thinning is performed between the steps (I) and (II).

6. The SOI wafer according to claim 2, wherein the first wafer to be processed is obtained with a pre-processing step in which a Smart Cut™ technology is performed.
